(19) United States
(12) Patent Application Publication
(10) Pub. No.: US 2026/0372219 A1
(43) Pub. Date: Nov. 19, 2026

(54) Semiconductor Device and Method of Making Having an Integrated-Glass IPD Substrate

(71) Applicant: STATS ChipPAC Management Pte. Ltd., Singapore (SG)

(72) Inventors: SeungMan Hong, Incheon (KR); YongTaek Lee, Seoul (KR); OhYoung Kwon, Seoul (KR); HeeSoo Lee, Incheon (KR); EunHee Myung, Gyeonggi-do (KR)

(73) Assignee: STATS ChipPAC Management Pte. Ltd., Singapore (SG)

(21) Appl. No.: 19/207,187

(22) Filed: May 13, 2025

(51) Int. Cl. H10W 99/00; H10W 70/692

(52) U.S. Cl. CPC H10W 99/00; H10W 70/692

(57) ABSTRACT

A semiconductor device has glass substrate. A cavity is etched into the glass substrate. A via opening is formed through the glass substrate. An integrated passive device (IPD) module is disposed into the cavity. An encapsulant is deposited over the glass substrate and IPD module. A first conductive layer is formed over the encapsulant. The first conductive layer forms a conductive via in the via opening and separately extends to the IPD module. A semiconductor die is mounted over the IPD module and encapsulant.

### FIELD OF THE INVENTION

The present invention relates in general to semiconductor devices and, more particularly, to semiconductor devices and methods of making having an integrated-glass integrated passive device (IPD) substrate.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Integrated passive devices (IPDs) are electronic components where resistors, capacitors, inductors, microstriplines, impedance matching elements, baluns, other similar elements, or combinations thereof are integrated in the same package or on the same substrate. Integrated passive devices can be packaged, bare dies/chips or even stacked with active integrated circuits, or other IPDs in an electronic system assembly.

The substrate for IPDs can be formed of any suitable rigid material, e.g., ceramic, glass, or silicon. Traditional silicon substrates have a high dielectric constant (Dk) and loss tangent (Df), resulting in signal loss. Glass substrates improve electrical performance but create issues with the IPD device layers having low adhesion and becoming separated from the substrate. Therefore, a need exists for new semiconductor devices and methods of making IPD structures with glass substrates.

### BRIEF DESCRIPTION OF THE DRAWINGS

FIGS. 1a-1c illustrate a semiconductor wafer with a plurality of semiconductor die separated by a saw street;

FIGS. 2a-2j illustrate forming an IPD structure;

FIGS. 3a-3k illustrate forming a semiconductor package having the IPD structure in integrated-glass IPD substrate; and

FIGS. 4a and 4b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention’s objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

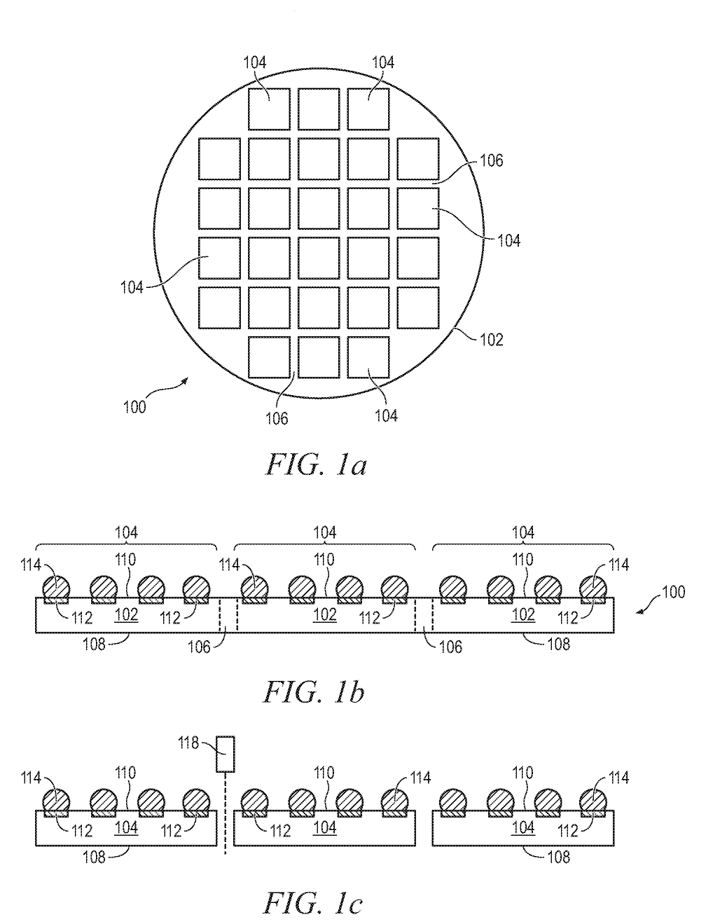

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bumps, micro bumps, or another type of electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

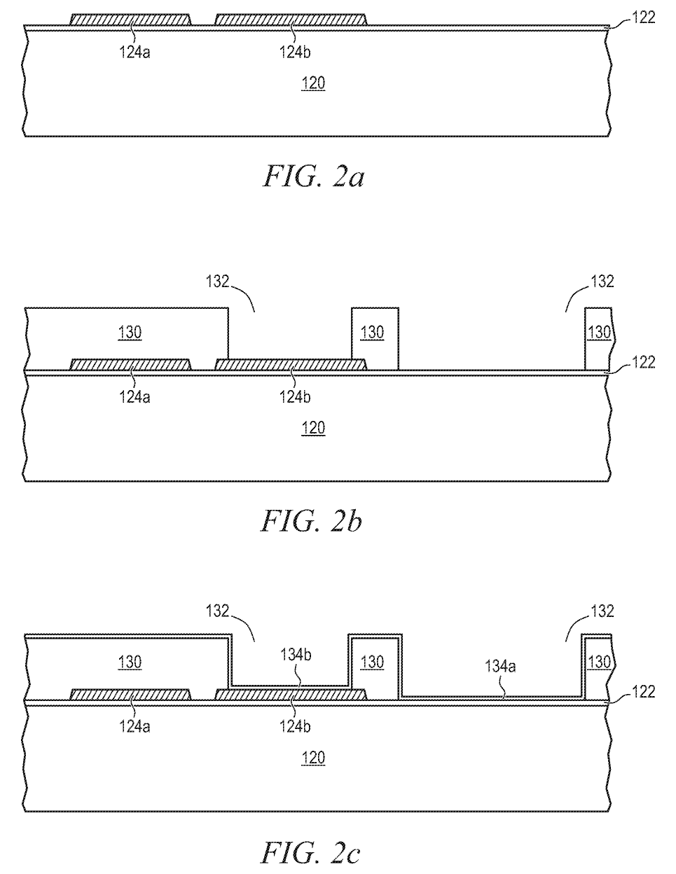

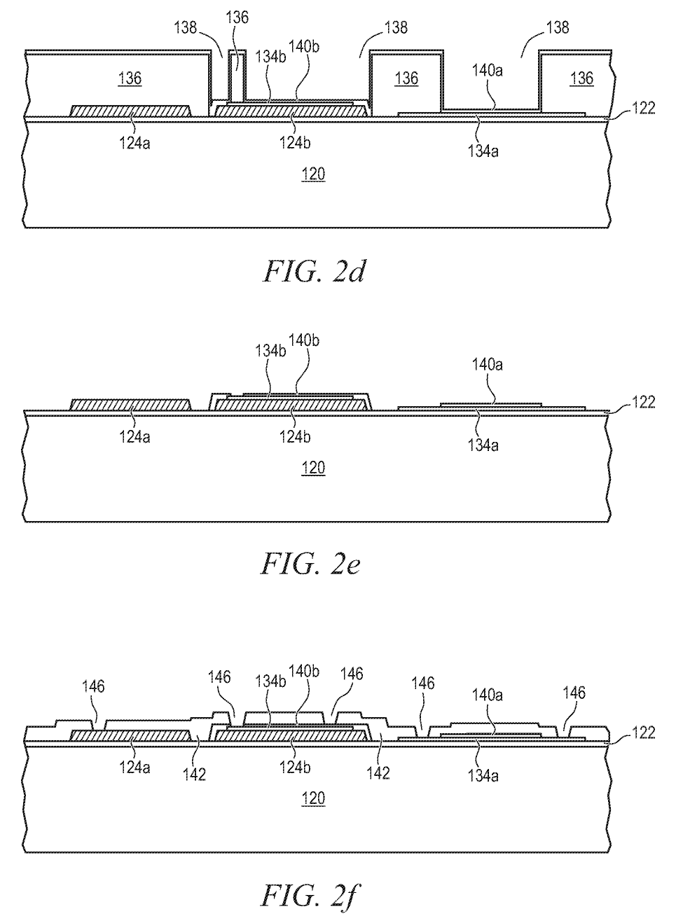

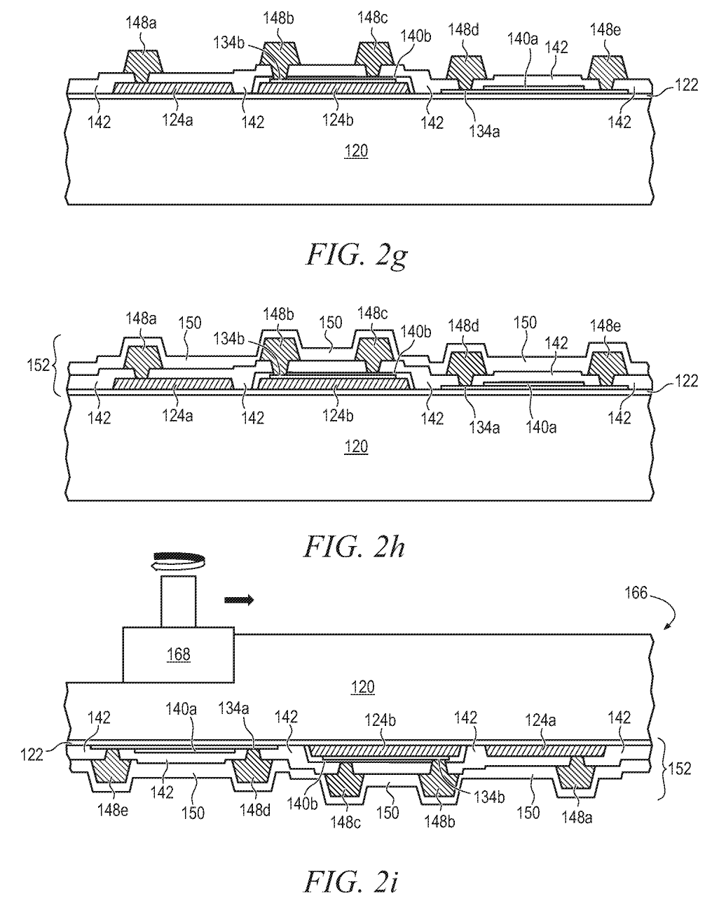

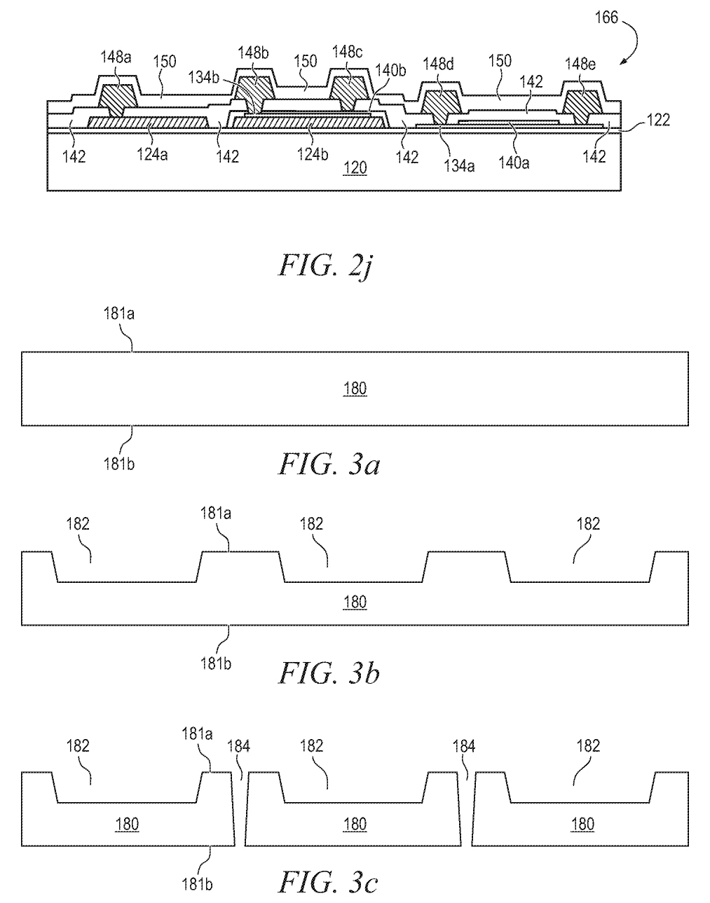

FIGS. 2a-2j illustrate forming integrated passive device (IPD) modules. IPDs are referred to as integrated because passive devices are formed over a substrate using common semiconductor manufacturing steps, allowing the IPDs to be integrated onto a semiconductor die with other functionality. A silicon substrate 120 is used in FIG. 2a. Substrate 120 can be the same or similar to wafer 100 in FIG. 1a. Substrate 120 may have active devices formed in the silicon material as with active surface 110 above, or the silicon material can be used only as a substrate for the overlying IPDs. Substrate 120 can also be other semiconductor material, aluminum, steel, copper, another metal, glass, polymer, or formed from any other suitable rigid material for structural support of the IPDs being formed.

An insulating layer 122 is formed over substrate 120. Insulating layer 122 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Any insulating layer mentioned herein can be formed using the same materials and methods described for insulating layer 122. Openings can be formed through insulating layer 122 to allow electrical connection if active circuit elements were formed in substrate 120.

A conductive layer 124 is formed over insulating layer 122. Conductive layer 124 can be one or more layers of Al, Cu, Sn, Ni, Au, Ag, or other suitable electrically conductive material. Conductive layers can be formed using PVD, CVD, electrolytic plating, electroless plating, or other suitable metal deposition process. Conductive layer 124 provides horizontal electrical interconnect across substrate 120. Portions of conductive layer 124 can be electrically common or electrically isolated depending on the design and function of the package being formed. Conductive layer 124 is deposited into optional openings of insulating layer 122 to physically and electrically connect to circuit elements in substrate 120, if formed. Conductive layer 124 is patterned using a photolithographic mask, etching after deposition, selective plating, or another suitable process.

Conductive layer 124 is formed in the same manner as a normal metal-1 (M1) layer over a semiconductor die or wafer. Portions of conductive layer 124 can be patterned to form integrated passive devices, e.g., shaped in coils to form part of inductors or as a capacitor plate. Portions of conductive layer 124 also form conductive traces across the surface of substrate 120 to act as a redistribution layer (RDL) and contact pads for contact with subsequently formed conductive layers or external devices. In particular, portion 124a in FIG. 2a is shaped to form a conductive trace with contact pads at its ends and portion 124b is shaped to form a contact pad connected to a bottom plate of a capacitor. Portions of conductive layer 124 can be shaped as desired to form any suitable circuit elements.

FIG. 2b shows a mask layer 130 formed over substrate 120. Mask layer 130 is a photolithographic mask that is formed completely covering substrate 120 and then developed to allow removal of desired portions to form openings 132. In FIG. 2c, a Tantalum-Silicon (TaSi) layer 134 is formed by depositing the appropriate materials into openings 132. TaSi layer 134 can be deposited using any of the methods discussed above for conductive layer 124. TaSi layer 134 is formed completely covering mask layer 130 and then only the portions on the bottom surfaces in openings 132 remain after removal of the mask. Openings 132 define the shape of TaSi layer 134 that is left in the final product after mask 130 is removed. In other embodiments, TaSi layer 134 is formed covering substrate 120 completely without a mask and then patterned to the desired structures or selectively formed in the desired pattern without a mask.

TaSi layer 134 is used as a layer with a controllable electrical resistance. In FIG. 2c, portion 134a is formed independently to operate as a resistor. Portion 134b is formed on conductive layer portion 124b to form part of the capacitor structure. TaSi layer 134 can be selectively formed using mask 130 with openings 132 into any desired pattern for forming any desired passive components over substrate 120.

In FIG. 2d, a second mask layer 136 is formed over substrate 120 with openings 138 formed through the mask layer. A nitride layer 140 is formed over mask 136 and into openings 138. Nitride layer 140 remains in the pattern of openings 138 after mask 136 is removed in FIG. 2e. In other embodiments, nitride layer 140 is formed covering substrate 120 completely without a mask and then patterned to the desired formations or selectively formed in the desired pattern without a mask.

Nitride layer portion 140b is an insulating layer that operates as a dielectric layer over the capacitor plate of conductive layer portion 124b. Nitride layer portion 140a provides a protective layer over the resistor formed by TaSi layer portion 134a. Nitride layer 140 can be formed in any suitable pattern to create the desired electrical components.

Insulating layer 142 is formed over substrate 120 in FIG. 2f. Openings 146 are formed through insulating layer 142 to expose underlying elements for electrical interconnect. Insulating layer 142 can be formed as discussed above for insulating layer 120 and patterned using photolithography, laser ablation, or another suitable means. Insulating layer 142 is a PI layer in one embodiment.

In FIG. 2g, a conductive layer 148 is formed over insulating layer 142, including extending into openings 146. Conductive layer 148 is formed and patterned as discussed above for conductive layer 124. Portion 148a operates as a contact pad for the conductive trace of conductive layer portion 124a. Portions 148b and 148c operate as contact pads for the underlying capacitor. Portions 148d and 148e operate as contact pads for the underlying resistor. Conductive layer 148 can be patterned into contact pads, conductive traces, and other structures to implement the desired electrical functionality.

Insulating layer 150 is formed over conductive layer 148 in FIG. 2h to complete IPD structure 152. Insulating layer 150 is formed as described above for insulating layer 142. Insulating layer 150 is a PI layer in one embodiment. Openings are formed through insulating layer 150 to expose contact pads of conductive layer 148 where needed for electrical interconnect. Conductive layers 124 and 148, nitride layer 140, TaSi layer 134, and any other layer formed of any other suitable material can be used to form any desired component as part of IPD structure 152.

FIG. 2i illustrates an optional backgrinding of substrate 120 to reduce a thickness of substrate 120 and thereby reduce a thickness of the final IPD module 166. Backgrinding is performed with a grinder 168 or other suitable means. The final IPD module 166 is illustrated in FIG. 2j. A plurality of IPD modules 166 are singulated from each other using a saw blade or laser cutting tool in embodiments where substrate 120 remains in wafer form during the manufacturing of IPD structures 152. IPD modules 166 are then placed into a JEDEC tray or tape-and-reel for distribution or immediately used in a larger electronic device or semiconductor package.

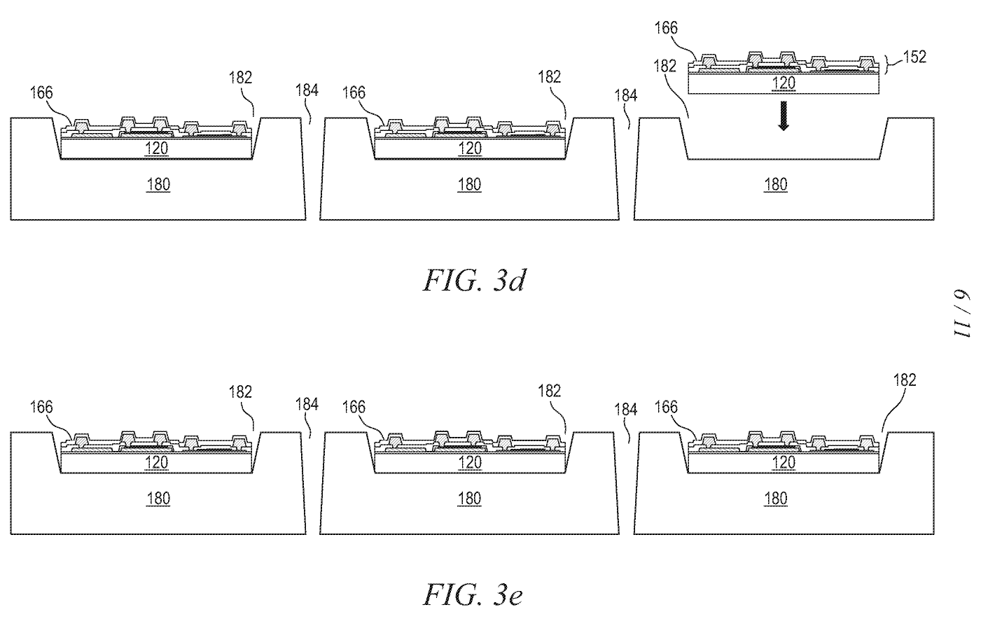

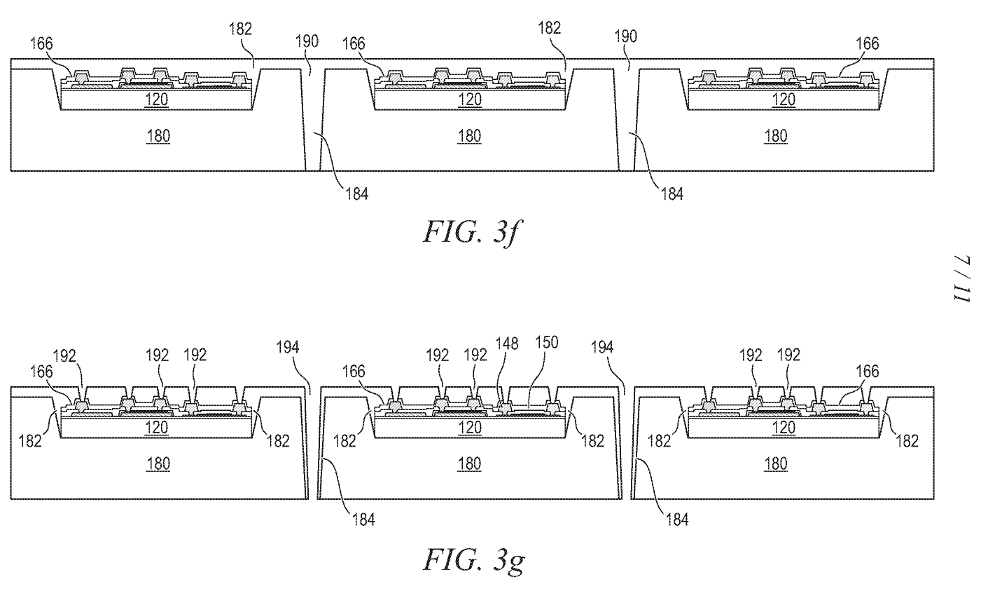

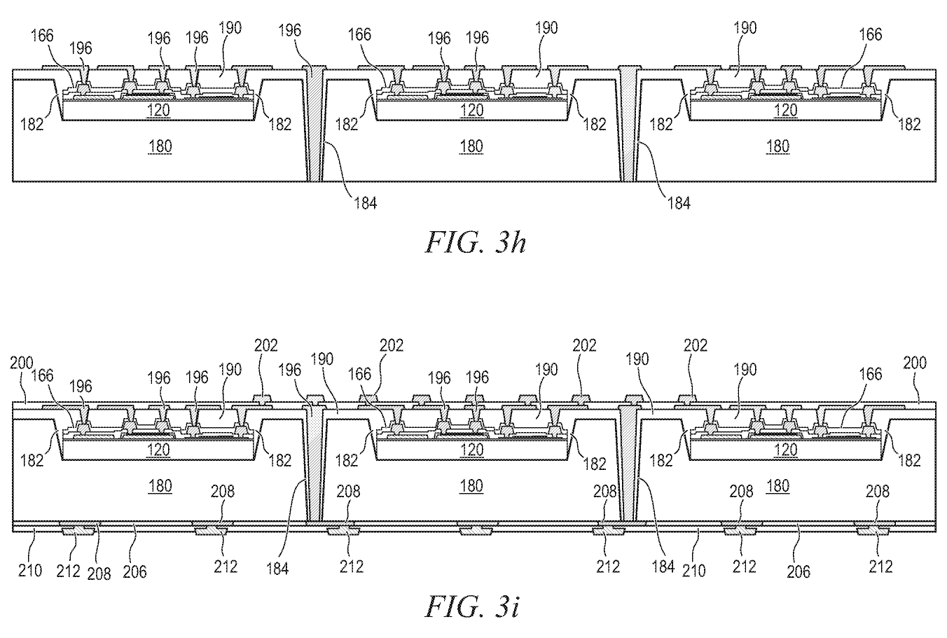

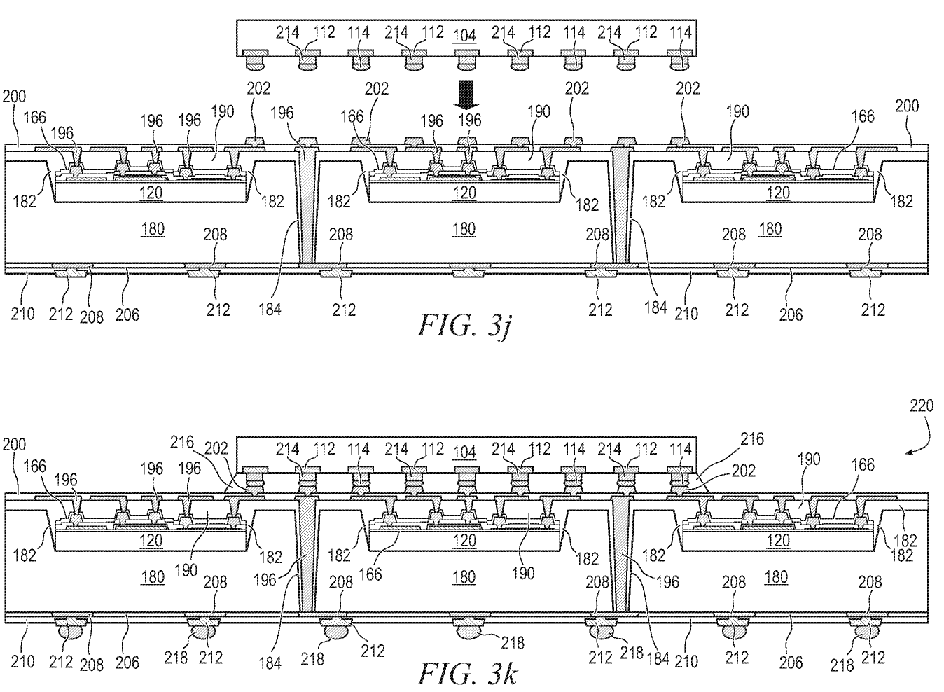

FIGS. 3a-3k illustrate a process of forming a semiconductor package having IPD modules 166 in an integrated-glass IPD substrate. FIG. 3a shows a glass substrate 180, e.g., a sheet of Corning glass. Glass substrate 180 is a high-purity borosilicate or aluminosilicate glass designed for semiconductor manufacturing. In one embodiment, glass substrate 180 comprises 60-80 per cent by weight of SiO₂, 5-20 per cent by weight of B₂O₃ or Al₂O₃, and 2 percent or less by weight of alkali oxides. Glass substrate 180 has low impurity levels (<10 ppm) and alkali content (<0.1 per cent by weight). Glass substrate 180 is formed via a float glass or fusion draw process.

In one embodiment, glass substrate 180 has a thickness of 0.3 mm to 1.1 mm, surface roughness (Ra) less than 0.5 nm, and a flatness of less than 1 µm bow/warp over 300 mm. A thickness of glass substrate 180 can be adjusted to benefit impedance matching with IPD modules 166. Annealing at 500-700° C and polishing with cerium oxide yields defect-free primary surfaces 181a and 181b compatible with nanoscale deposition. Surfaces 181a and 181b are equivalent and interchangeable. Glass substrate 180 exhibits a low coefficient of thermal expansion (~3.0-4.5 × 10⁻⁶/°C), high transparency (>90% at 300-800 nm), and thermal stability up to 600° C, making it ideal for advanced semiconductor processes, including thin-film deposition and EUV lithography.

In FIG. 3b, cavities 182 are formed into surface 181a by a wet etching or other suitable process. Wet etching allows the formation of precise, high-aspect-ratio features. The wet etching process begins with surface cleaning to ensure a contaminant-free surface. A hard mask, such as 100-200 nm silicon nitride or 50/150 nm chromium/gold, is deposited via PECVD or sputtering and patterned through photolithography with a photoresist layer to define cavity geometries with feature resolutions down to 1 µm. Wet etching is conducted by immersing the substrate in a buffered hydrofluoric acid solution, e.g., 5-20% hydrofluoric acid (HF) with ammonium fluoride (NH₄F) at an appropriate ratio as a buffering agent, at 20-40° C, achieving etch rates of 0.1-1 µm/min. Agitation via ultrasonic or mechanical stirring ensures uniform etchant distribution, forming cavities 182 with depths of 10-200 µm, sidewall angles of 80-90°, and internal surface roughness below Ra 10 nm. Post-etching, the mask is stripped using selective etchants, e.g., hot phosphoric acid for silicon nitride, followed by cleaning, rinsing, and drying under nitrogen. Cavities 182, with widths from 10 µm to 1 mm and aspect ratios up to 10:1, are thus formed with smooth, crack-free surfaces. Other processes are used to form cavities 182 in other embodiments.

Cavities 182 are configured in a suitable size, shape, and depth to house IPD modules 166 in a later step. Cavities 182 are formed to a depth sufficient to completely contain IPD modules 166 in some embodiments, i.e., a depth of the cavities is greater than a thickness or height of the IPD modules. The footprints of the bottom surfaces of cavities 182 are the same as or slightly larger than the footprints of IPD modules 166.

Through-glass vias (TGVs) 184 are formed through glass substrate 180 between cavities 182 in FIG. 3c. TGVs 184 are formed in glass substrate 180 between cavities 182 using a laser drilling process to enable vertical electrical interconnects between surfaces 181a and 181b. In one embodiment, the process employs a pulsed ultraviolet (UV) laser, typically a nanosecond or picosecond laser with a wavelength of 248-355 nm, delivering pulse energies of 100-500 µJ at a repetition rate of 10-100 kHz. The laser is focused on the substrate surface, ablating material to create vias with diameters of 10-50 µm and depths matching the substrate thickness.

Post-drilling, TGVs 184 are cleaned with a brief ultrasonic rinse in deionized water to remove residual ablation products, achieving smooth sidewalls with roughness (Ra) less than 50 nm and taper angles of 85-90°. The resulting TGVs 184 provide high-aspect-ratio interconnect pathways, enabling reliable metallization and integration in 3D packaging. In some embodiments, TGVs 184 are formed in cavities 182 to allow direct coupling from bottom surface 181b to the IPD modules 166 to be disposed in the cavities. TGVs 184 are typically small and circular in plan view. Therefore, the discrete portions of glass substrate 180 shown in FIG. 3c remain connected to each other as a continuous glass substrate in other cross-sections.

IPD modules 166 are picked and placed into cavities 182 in FIG. 3d. Substrate 120 is oriented toward glass substrate 180. A die-attach film or other adhesive is disposed in cavities 182 or on substrate 120 to attach IPD modules 166 in some embodiments. FIG. 3e shows glass substrate 180 with IPD modules 166. IPD modules 166 can all be identical, or each can have different circuits formed for different purposes and have different shapes.

A molding compound or encapsulant 190 is deposited over glass substrate 180 and IPD modules 166 in FIG. 3f. Encapsulant 190 is deposited using a paste printing, compression molding, transfer molding, liquid encapsulant molding, vacuum lamination, spin coating, or other suitable applicator. Encapsulant 190 can be liquid or granular polymer composite material, such as epoxy resin, epoxy acrylate, or another suitable polymer, with or without a filler. Encapsulant 190 is non-conductive, provides structural support, and environmentally protects the semiconductor device from external elements and contaminants. Encapsulant 190 fills cavities 182 and TGVs 184 and completely covers top and side surfaces of IPD modules 166.

Vias 192 and 194 are formed through encapsulant 190 using chemical etching, laser etching, mechanical drilling, or another suitable process in FIG. 3g. Vias 192 extend through encapsulant 190 and insulating layer 150 of IPD modules 166 to expose underlying contact pads of conductive layer 148. Vias 194 extend through TGVs 184 completely through the entire thickness of glass substrate 180 and encapsulant 190.

A conductive layer 196 is formed over encapsulant 190 and into vias 192 and 194 in FIG. 3h. Conductive layer 196 is formed using any of the methods and materials described above for conductive layers, e.g., conductive layers 112 and 124. Conductive layer 196 has conductive vias in vias 192 and 194, contact pads on the top surface of encapsulant 190, and conductive traces interconnecting the two in a fan-out or fan-in configuration. The individual portions of conductive layer 196 shown in FIG. 3h can be electrically common or electrically isolated depending on the electrical design of the system being formed.

In some embodiments, conductive layer 196 is formed using a semi-additive process to create precise metallic patterns for electrical interconnects. The process begins with the deposition of a thin seed layer, typically 50-100 nm of copper or titanium/copper, over glass substrate 180 and within vias 192 and 194 via physical vapor deposition (PVD) or electroless plating, ensuring conformal coverage. A photoresist layer is then applied and patterned using photolithography to define the desired conductive traces with feature resolutions down to 2 µm. Electroplating is performed to selectively deposit a thicker copper layer (5-20 µm) onto exposed seed layer areas, forming the conductive patterns. The photoresist is stripped using a chemical solvent, and the exposed seed layer is removed by selective wet etching, e.g., using ammonium persulfate for copper, leaving the patterned conductive layer 196. The substrate is cleaned with deionized water and dried under nitrogen. Any other suitable conductive layer forming process is used in other embodiments.

An insulating or passivation layer 200 is formed over conductive layer 196 and encapsulant 190 in FIG. 3i. Insulating layer 200 is formed using any of the materials and methods described above for insulating layers generally. A build-up interconnect structure can be formed by successively forming additional conductive layers 196 and insulating layers 200 interleaved over glass substrate 180. Any number of conductive layers 196 can be used to achieve the desired signal routing. Each conductive layer 196 is electrically and physically coupled to an underlying conductive layer through openings in an underlying insulating layer. Contact pads or under-bump metallization (UBM) pads 202 are formed over insulating layer 200 and extend into openings of the insulating layer to physically and electrically contact the underlying conductive layer 196.

Substrate 180 is flipped to allow the formation of a build-up interconnect structure on the bottom surface in the manner just described for the top surface. Insulating layers 206 and conductive layers 208 are interleaved over the bottom surface of glass substrate 180 to achieve the desired signal routing. Conductive layer 208 fans out or in electrical connections from conductive vias of conductive layer 196. UBM pads 212 are formed over the top insulating layer 206 and conductive layer 208. Conductive layer 208 can be formed directly on glass substrate 180, or an insulating layer 206 can be laid down first. An optional solder resist or passivation layer 210 is formed over UBM pads 212, insulating layer 206, and conductive layer 208. UBM pads 212 are electrically coupled to UBM pads 202 through conductive layers 208 and 196.

Glass substrate 180 with IPD modules 166 and encapsulant 166, having been metalized on both sides, is an integrated-glass IPD substrate, meaning a substrate formed of glass with IPDs integrated into the substrate. The substrate as shown in FIG. 3i can be used as a package substrate to form any suitable type of semiconductor package.

As one simple example, a semiconductor die 104 is picked and placed over UBM pads 202 in FIG. 3j. Any other desired components can be disposed over substrate 180 along with semiconductor die 104, e.g., chiplets, subpackages, additional bare die, or discrete active or passive components. Semiconductor die 104 has optional conductive pillars or stud bumps 214 formed between conductive layer 112 and solder bumps 114. Semiconductor die 104 is set down with solder bumps 114 on UBM pads 202 in FIG. 3k. Solder bumps 114 are reflowed to physically and electrically couple semiconductor die 104 to UBM pads 202.

An optional mold underfill 216 is dispensed between semiconductor die 104 and insulating layer 200. Solder bumps 218 are formed on UBM 212 as described above for solder bumps 114. Solder bumps 218 allow integration of the final semiconductor package 220 into a larger electrical system. Other types of interconnect structures are used in other embodiments. In some embodiments, glass substrate 180 is a large panel with multiple packages 220 formed at once, which are singulated from each other using a laser cutting tool or saw blade to separate the units after completion.

Placing glass substrate 180 under substrate 120 enhances electrical performance and stability of IPD module 166 due to the low Dk, Df, and dissipation factor of glass. In particular, the low Df of glass substrate 160 boosts the Q-factor of inductor structures. This approach not only improves the electrical performance but also enhances the manufacturing efficiency and reliability of the semiconductor devices. By using a silicon wafer 120 to implement the interposer layer, the risk of the RDL layer detaching from glass substrate 160 is reduced.

By stacking more components within the same area, the manufacturing process benefits from improved efficiency and cost-effectiveness. Utilizing trenching enables a stable IPD process, and, when various material properties are required, an optimized substrate selection is possible. While conductive layer 196 is used to electrically couple semiconductor die 104 to IPD modules 166, the interconnect could be made by bond wire or another suitable interconnect structure. While three IPD modules 166 are illustrated, a package could be made with only a single IPD module 166 directly under a semiconductor die 104, or any other suitable number of IPD modules can be included. The final package can be connected to an external system by bond wires coupled to conductive layer 196 rather than having conductive vias of conductive layer 196 extending through glass substrate 180 and a bottom-side interconnect structure.

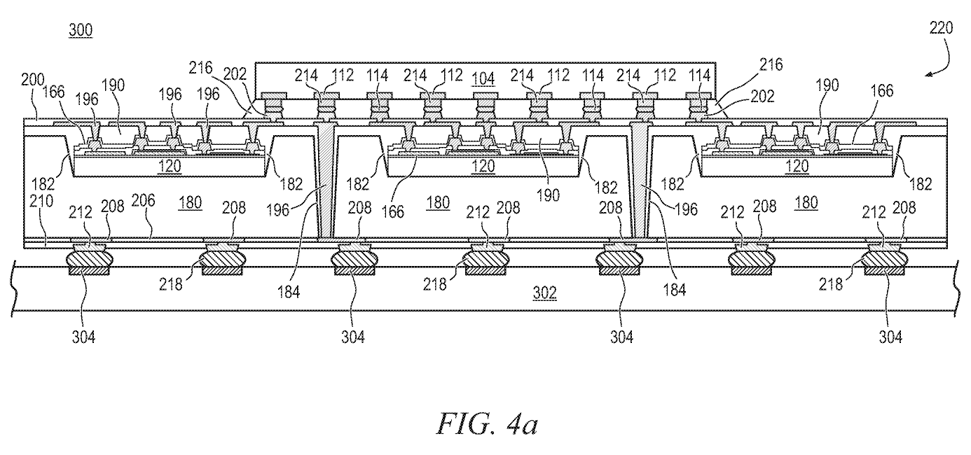

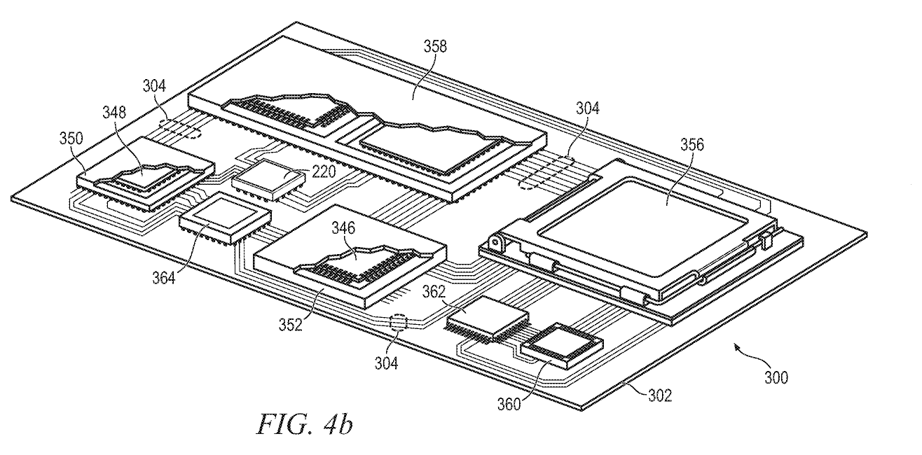

FIGS. 4a and 4b illustrate integrating the above-described semiconductor packages, e.g., semiconductor package 220, into a larger electronic device 300. FIG. 4a illustrates a partial cross-section of semiconductor package 220 mounted onto a printed circuit board (PCB) or other substrate 302 as part of electronic device 300. Solder bumps 218 are reflowed onto conductive layer 304 of PCB 302 to physically attach and electrically connect semiconductor package 220 to the PCB. In other embodiments, thermocompression or another suitable attachment and connection methods are used. In some embodiments, an adhesive or underfill layer is used between semiconductor package 220 and PCB 302. Semiconductor die 104 is electrically coupled to conductive layer 304 through bumps 218, conductive layers 208 and 196, and UBM pads 212 and 202.

FIG. 4b illustrates electronic device 300 having a chip carrier substrate or PCB 302 with a plurality of semiconductor packages disposed on a surface of PCB 302, including semiconductor package 220. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 4b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a glass substrate;
etching a cavity into the glass substrate;
forming a via opening through the glass substrate;
disposing an integrated passive device (IPD) module into the cavity;
depositing an encapsulant over the glass substrate and IPD module;
forming a first conductive layer over the encapsulant, wherein the first conductive layer forms a conductive via in the via opening and separately extends to the IPD module; and
mounting a semiconductor die over the IPD module and encapsulant.

2. The method of claim 1, further including forming the via opening by laser drilling.

3. The method of claim 1, further including etching the cavity using wet etching.

4. The method of claim 1, further including:
forming the IPD module on a silicon substrate; and
disposing the IPD module with the silicon substrate oriented toward the glass substrate.

5. The method of claim 1, further including forming a second conductive layer over the glass substrate opposite the first conductive layer, wherein the conductive via electrically connects the first conductive layer to the second conductive layer.

6. The method of claim 1, further including:
forming an opening through the encapsulant to expose a contact pad of the IPD module; and
forming the first conductive layer extending into the opening to extend to the IPD module.

7. A method of making a semiconductor device, comprising:
providing a glass substrate;
etching a cavity into the glass substrate;
disposing an integrated passive device (IPD) module into the cavity;
depositing an encapsulant over the glass substrate and IPD module; and
mounting a semiconductor die over the IPD module and encapsulant.

8. The method of claim 7, further including forming a via opening through the glass substrate.

9. The method of claim 7, further including:
forming the IPD module on a silicon substrate; and
disposing the IPD module with the silicon substrate oriented toward the glass substrate.

10. The method of claim 7, further including forming a first conductive layer over the glass substrate, IPD module, and encapsulant.

11. The method of claim 10, further including forming a second conductive layer over the glass substrate opposite the first conductive layer, wherein the first conductive layer includes a conductive via extending to the second conductive layer.

12. The method of claim 10, further including:
forming an opening through the encapsulant to expose a contact pad of the IPD module; and
forming the first conductive layer extending into the opening to extend to the IPD module.

13. The method of claim 7, further including etching the cavity to include a height greater than a height of the IPD module.

14. A semiconductor device, comprising:
a glass substrate;
a cavity formed in the glass substrate;
a via opening formed through the glass substrate;
an integrated passive device (IPD) module disposed in the cavity;
an encapsulant deposited over the glass substrate and IPD module;
a first conductive layer formed over the encapsulant, wherein the first conductive layer forms a conductive via in the via opening and separately extends to the IPD module; and
a semiconductor die mounted over the IPD module and encapsulant.

15. The semiconductor device of claim 14, wherein the IPD module fits completely within the cavity.

16. The semiconductor device of claim 14, wherein the first conductive layer extends through the encapsulant to contact the IPD module.

17. The semiconductor device of claim 14, wherein the IPD module includes a silicon substrate oriented toward the glass substrate.

18. The semiconductor device of claim 14, further including a second conductive layer formed over the glass substrate opposite the first conductive layer, wherein the conductive via electrically connects the first conductive layer to the second conductive layer.

19. The semiconductor device of claim 14, further including an insulating layer formed over the first conductive layer.

20. A semiconductor device, comprising:
a glass substrate;
a cavity formed in the glass substrate;
an integrated passive device (IPD) module disposed in the cavity;
an encapsulant deposited over the glass substrate and IPD module; and
a semiconductor die disposed over the IPD module and encapsulant.

21. The semiconductor device of claim 20, further including a via opening formed through the glass substrate.

22. The semiconductor device of claim 20, wherein the IPD module includes a silicon substrate oriented toward the glass substrate.

23. The semiconductor device of claim 20, further including a first conductive layer formed over the glass substrate, IPD module, and encapsulant.

24. The semiconductor device of claim 23, further including a second conductive layer formed over the glass substrate opposite the first conductive layer, wherein the first conductive layer and second conductive layer are electrically coupled to each other by a conductive via.

25. The semiconductor device of claim 20, wherein a height of the cavity is greater than a height of the IPD module.
